(19) United States
(12) Patent Application Publication
(10) Pub. No.: US 2010/0237362 A1
(43) Pub. Date: Sep. 23, 2010

(54) DISPLAY DEVICE AND PRODUCTION METHOD THEREOF

(75) Inventor: Tohru Okabe, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/682,065

(22) PCT Filed: May 20, 2008
(86) PCT No.: PCT/JP2008/059235

§ 371 Date: Apr. 8, 2010

(30) Foreign Application Priority Data
Oct. 23, 2007 (JP) 2007-275376

(51) Int. Cl. H01L 27/15; H01L 33/50; H01L 33/44

(52) U.S. Cl. 257/88; 438/30; 438/29; 257/E33.061; 257/E33.067; 257/E27.12

(57) ABSTRACT

The present invention provides a display device capable of suppressing deterioration of characteristics of a display element even when a resin is used as a material for a substrate. A display device of the present invention comprises: a resin substrate; and
an organic insulating film, an inorganic conductive film, and a display element, formed on the resin substrate in this order,
wherein the display device comprises an inorganic insulating film arranged adjacent to the inorganic conductive film, the inorganic insulating film and the inorganic conductive film covering the entire surface of the organic insulating film.

### TECHNICAL FIELD

The present invention relates to a display device and a production method of the display device. More particularly, the present invention relates to a display device including a substrate of a resin material and a production method of such a display device.

### BACKGROUND ART

Examples of display panels used in electronic apparatuses such as a television, a personal computer, a mobile phone, and a digital camera, which are commonly used in recent years, include a liquid crystal display (LCD) panel, a plasma display panel (PDP), and an electroluminescent (EL) display panel.

Such display panels each include a display element. For example, an LCD panel includes a liquid crystal layer containing liquid crystal materials; a PDP includes a plasma discharge tube; and an EL panel includes a light-emitting layer made of a light emitter. These display elements play an important role in the corresponding display panel.

Particularly, in the LCD panel, the liquid crystal layer controls light used for display and therefore characteristics of the liquid crystal layer are closely related to display characteristics. As a method for keeping moisture resistance, pressure resistance, and moisture-holding property of the liquid crystal (resin) layer and preventing oxidation of the liquid crystal (resin) layer, Patent Document 1 discloses, for example, a configuration where a gas barrier structure including a metal layer or an inorganic oxide layer on the liquid crystal (resin) layer.

Such a display panel is usually made using a substrate as a base component, and a circuit element, a controlling element, and the like are arranged on the substrate to complete a display device. As a material for the substrate, glass is commonly used in view of insulation, pressure resistance, and heat resistance.

Resins may also be used as a material for the substrate, instead of glass. Such a resin substrate provides a light-weight display panel with excellent flexibility that a glass substrate cannot give.

However, the resin substrate easily allows moisture or oxygen to permeate it compared with a glass substrate. In addition, a liquid crystal is very sensitive to moisture and oxygen. In this respect, use of the resin substrate in a liquid crystal display device has room for improvement.

### [Patent Document 1]

Japanese Kokai Publication No. Hei-10-202780

### DISCLOSURE OF INVENTION

The present invention has been made in view of the above-mentioned state of the art. The present invention has an object to provide a display device capable of suppressing deterioration of characteristics of a display element even when a resin is used as a material for a substrate.

As a configuration of a display device including a resin substrate, the following specific configurations are described. FIG. 6 is a cross-sectional view schematically showing a configuration of a common liquid crystal display device including a resin substrate.

When a liquid crystal display device includes a resin substrate in place of a glass substrate, as shown in FIG. 6, a pair of resin substrates 111 and 121 is arranged with a liquid crystal layer 110 therebetween, the liquid crystal layer 110 being a display element of the liquid crystal display device. The resin substrates 111 and 121 are attached to each other with a sealing member 120. One example of a configuration of the liquid crystal display device is that the substrate 111 includes an electrode 115 and the substrate 121 includes an electrode 125, the electrodes 115 and 125 facing to each other. These electrodes 115 and 125 are applied with an voltage to create an electric field in the liquid crystal layer 110 and control alignment of liquid crystal molecules in the layer 110, thereby adjusting refraction of light from a backlight and the like. In such a manner, a liquid crystal display mode of white state and black state is controlled.

In such a configuration, an inorganic base coat film 112 is typically formed on the resin substrate 111 as a moisture barrier film, and in a desired region on the film 112, a TFT (thin film transistor) 113 is arranged and an organic interlayer insulating film 114 is formed to cover the TFT 113 and the inorganic base coat film 112, and further thereon, the pixel electrode 115 is formed for each pixel (hereinafter, such a structure is also referred to as “array substrate”). An inorganic base coat film 122 is formed on the resin substrate 121 as a moisture barrier film, and thereon, a color filter 123 and a black matrix 124 are formed, and a counter electrode 125 is formed on the entire surface of the color filter 123 and the black matrix 124 (hereinafter, such a structure is also referred to as “counter substrate”). The color filter 123 is generally composed of three color filters of red 123R, green 123G, and blue 123B. Such a configuration permits the control of a hue and a brightness of display in each region where the pixel electrode 115 is formed.

The inventor has found that a liquid crystal display device including a resin substrate has the following problem. When making a resin substrate having a thickness of about 100 μm, application of a large amount of a liquid resin and heat curing treatment for the applied resin are generally performed, which results in generation of micron-scale foreign substances or irregularities on the surface of the resin substrate. The foreign substances and the irregularities of thus-prepared resin substrate may not be completely covered by moisture barrier film such as an inorganic base coat film which is formed by usual methods.

Specifically, as shown in FIG. 6, organic foreign substances 130 like the above foreign substances deposited on the resin substrate 111 make regions on the resin substrate 111 where no inorganic base coat film 112 is formed. In an array substrate, moisture and oxygen entering from a surface or an edge face of the resin substrate 111 penetrate into the organic interlayer insulating film 114 via the organic foreign substances 130, and further permeate into the liquid crystal layer 110 through a space between the pixel electrodes 115. In a color filter substrate, moisture and oxygen entering from a surface or an edge face of the resin substrate 121 penetrate into a color filter 123 and a black matrix 124, and further permeate into the liquid crystal layer 110 from a region where no counter electrode 125 is formed. In FIG. 6, the dotted arrow shows a path of permeation of moisture and oxygen.

Liquid crystal materials are sensitive to moisture. So in such a configuration, the moisture or oxygen does not affect characteristics of the liquid crystal layer in the short term, but in the long term, it accelerates deterioration of characteristics of the liquid crystal layer.

The present inventor made various investigations on a configuration of the display device in which the deterioration of characteristics is suppressed and noted an arrangement configuration of an inorganic film. The inventor has found that an inorganic film effectively prevents permeation of moisture and oxygen and that an additional inorganic film arranged to face the entire surface of a display element effectively suppresses deterioration of characteristics of the display device. In conventional display devices, a pixel electrode is formed to face only a part of the liquid crystal layer because a system for driving each pixel is excellent as a display system. In such a case, the inventor has also found that an additional inorganic film arranged in a space between the pixel electrodes can effectively prevent permeation of moisture and oxygen, which provides significant advantages to the prevention of deterioration of characteristics of the display element. Thus, the above-mentioned problems have been admirably solved, leading to completion of the present invention.

That is, the present invention is a display device includes: a resin substrate; and an organic insulating film, an inorganic conductive film, and a display element, formed on the resin substrate in this order, wherein the display device includes an inorganic insulating film arranged adjacent to the inorganic conductive film, and the inorganic insulating film and the inorganic conductive film covering the entire surface of the organic insulating film.

The display device of the present invention is described below in more detail.

The display device of the present invention includes: a resin substrate; and an organic insulating film, an inorganic conductive film, and a display element, formed on the resin substrate in this order. In the present description, a resin means polymer plastic substances showing composition fluidity by application of heat or pressure and includes both thermoplastic resins and thermosetting resins. The organic insulating film may be used, for example, as a film that insulates various wirings such as a gate signal line and a data signal line on a substrate and a switching element such as a TFT, from the inorganic conductive film formed thereon, but is not limited to such a use. The inorganic conductive film may be used, for example, as an electrode for driving a display element, but is not limited to such a use. Examples of the display element includes: a liquid crystal layer constituted by a liquid crystal material; an organic EL layer and an inorganic EL layer constituted by a material exhibiting luminescence characteristics by voltage application; and what is called an electronic paper in which particles move by voltage application. The use of the display element is not particularly limited and the display element may be used as an element constituted by functional materials that is susceptible to moisture, oxygen and the like.

The display device of the present invention includes the inorganic insulating film arranged adjacent to the inorganic conductive film, and the inorganic insulating film and the inorganic conductive film covering the entire surface of the organic insulating film. In the present description, the inorganic insulating film is in principle formed adjacent to the inorganic conductive film in order to cover a surface of the organic insulating film in a region other than a region where the inorganic conductive film is formed. The inorganic insulating film and the inorganic conductive film may overlap with each other as long as they cover the entire surface of the organic insulating film.

The inorganic conductive film may be used as an electrode and the like, so a design thereof may be restricted. In contrast, a thickness of the inorganic insulating film can be designed with high degree of freedom unlike a film for forming an electrode. Because of this, the above-mentioned inorganic insulating film is preferably formed to have a thickness larger than that of the inorganic conductive film. Such an inorganic insulating film being set to have a thickness larger than that of the inorganic conductive film has an improved coating property for organic foreign substances and enhanced reliability of the prevention of display deterioration.

The display device of the present invention includes the organic insulating film on the substrate, and the substrate and the organic insulating film may be in a path of permeation of moisture and oxygen. In contrast, the inorganic conductive film and the inorganic insulating film do not generally permeate moisture and oxygen. Therefore, according to the present invention, the inorganic conductive film and the inorganic insulating film covering the surface of the organic insulating film effectively prevent permeation of moisture and oxygen, which cannot be prevented only with an electrode used for display, into a display element, and prevent deterioration of characteristics of the display element.

In the present description, a configuration that “covering the entire surface” represents is not limited to a configuration in which a surface is completely covered. Specifically, in the present invention, the inorganic insulating film and the inorganic conductive film substantially cover the entire surface of the organic insulating film and may not cover a portion of the organic insulating film. Although the inorganic conductive film and the inorganic insulating film are formed to cover the organic insulating film surface in the display device of the present invention, organic foreign substances might be deposited also on the organic insulating film, like on a resin substrate, in its production process. In this case, a portion of the organic insulating film can not covered by the inorganic conductive film and the inorganic insulating film. According to the present invention, a sufficient long path of permeation of moisture and oxygen can be secured, so even if such an uncovered portion is generated, an effect of preventing the permeation of moisture and oxygen can be obtained as long as the inorganic conductive film and the inorganic insulating film are formed over the substantially entire surface of the organic insulating film.

The reason why the permeation of moisture and oxygen is prevented when a long path of permeation thereof is secured is mentioned below. A permeation amount (speed) of moisture and oxygen can be represented by the formula “permeation speed (permeation amount)=area of path of permeation×thickness of path of permeation/permeation time (distance of path of permeation)”. The formula shows that the path of permeation with a longer distance can reduce the permeation speed (permeation amount).

As long as the display device of the present invention essentially includes the above-mentioned components, the display device may or may not include other components. For example, the display device may further include a driver for display control, a light source emitting light for display, an optical film for light control, and the like.

Hereinafter, preferred embodiments of the display device of the present invention are described in detail.

The display device of the present invention preferably includes an inorganic base coat film disposed between the resin substrate and the organic insulating film, the inorganic base coat film covering the entire surface of the resin substrate.

In the present description, the inorganic base coat film is an inorganic film provided in contact with the resin substrate. Such an inorganic base coat film serves as one film that separates the resin substrate from the organic insulating film and prevents permeation of moisture and oxygen. Thus, moisture and oxygen from a substrate surface are more effectively prevented from permeating the display device. As mentioned above, a configuration that “covering the entire surface” represents is not limited to a configuration in which a surface is completely covered. Specifically, in the present configuration, the inorganic base coat film substantially cover the entire surface of the resin substrate and may not cover a portion of the resin substrate. The resin substrate is used in the present invention, so an organic foreign substrate might be deposited thereon and this generates such an uncured portion of the resin substrate. According to the present embodiment, a sufficient long path of permeation of moisture and oxygen can be secured, so even if such an uncovered portion is generated, an effect of significantly suppressing the permeation of moisture and oxygen can be obtained as long as the inorganic base coat film is formed in the substantially entire surface of the resin substrate.

The above-mentioned inorganic base coat film is preferably arranged on both surfaces of the resin substrate. Moisture and oxygen permeate the resin substrate from the outside. So the permeation thereof into a display element can be overall suppressed by reducing an area of the resin substrate exposed to the outside. Specifically, the permeation of moisture and oxygen from the substrate surface is prevented, and the permeation is only from a substrate edge face, which has an area smaller than that of the substrate surface. Thus, according to the present embodiment, the permeation of moisture and oxygen to the display element can be further prevented.

The above-mentioned display preferably includes gate signal lines, data signal lines, and thin film transistors on the resin substrate, wherein the inorganic conductive film constitutes a pixel electrode arranged in a region surrounded by the gate signal lines and the data signal lines.

The gate signal lines and the data signal lines are generally arranged perpendicular to each other and the thin film transistor (TFT) is arranged at each of the intersections of the lines. The pixel electrode is formed for each pixel that a region surrounded by the gate signal lines and the data signal lines constitutes. So the pixel electrode is generally formed not to cover the entire organic insulating film mentioned above. Therefore, the present invention is suitable for formation of such a display device in which driving thereof is controlled on a pixel basis.

The above-mentioned organic insulating film preferably constitutes a color filter. That is, the present embodiment is an embodiment that the organic insulating film is used as the color filter. According to the present embodiment, even if the color filter is not covered with an electrode due to organic foreign substances that are formed on the color filter in the production process, permeation of moisture and oxygen into the display element can be prevented.

The above-mentioned organic insulating film preferably constitutes a black matrix. That is, the present embodiment is an embodiment that the organic insulating film is used as the black matrix. According to the present embodiment, even if the black matrix is not covered with an electrode due to organic foreign substances that are formed on the black matrix in the production process, permeation of moisture and oxygen into the display element can be prevented.

The above-mentioned organic insulating film preferably has a thickness of not more than 10 μm. As mentioned above, a permeation amount (speed) of moisture and oxygen can be represented by the formula “permeation speed (permeation amount)=area of path of permeation×thickness of path of permeation/permeation time (distance of path of permeation).

The formula that the reduction in the thickness of the path of permeation can reduce the permeation speed (permeation amount). This shows that the reduction in the thickness of the organic insulating film, which is the path of permeation, can reduce permeation speed (permeation amount). The present embodiment is based on such a principle. Thereby, when the organic insulating film has a thickness of not more than 10 μm that is thinner than that of a conventional one, permeation of moisture and oxygen into the display element can be effectively prevented. Such an organic insulating film formed to have a thin thickness reduces a size of organic foreign substances generated thereon, and therefore the inorganic insulating film and the inorganic conductive film cover the surface of the organic insulating film with ease.

The above-mentioned display element is preferably a liquid crystal layer. That is, the present embodiment is an embodiment that the display device of the present invention is applied to a liquid crystal display device. A liquid crystal layer is generally sensitive to moisture and oxygen, and the moisture and oxygen deteriorate characteristics of the liquid crystal layer. So, the present invention is effectively applied to the liquid crystal display device.

The above-mentioned display element is preferably an electroluminescent layer. That is, the present embodiment is an embodiment that the display device of the present invention is applied to an electroluminescent (EL) display device. The EL layer constituted by an organic EL or an inorganic EL is generally also sensitive to moisture and oxygen, and the moisture and oxygen deteriorate characteristics of the EL layer. So, the present invention is effectively applied to the EL display device.

The production method of the display device of the present invention is described in detail below.

The present invention is a production method of the display device of the present invention including a step of forming the inorganic insulating film by chemical vapor deposition. That is, the present production method is a method for producing the inorganic insulating film that is arranged to be adjacent to the inorganic conductive film and covers the entire surface of the organic insulating film together with the inorganic conductive film. By CVD (Chemical Vapor Deposition), a dense inorganic insulating film can be formed to cover the organic foreign substances formed on the organic insulating film with high coating property, thereby significantly reducing a probability of pinhole generation due to a coating defect. As a result, permeation of moisture and oxygen into a display element can be effectively prevented, which provides a display device including the display element in which deterioration of characteristics is suppressed.

If a film is formed by CVD process, its coating property is typically enhanced with an increase in temperature and pressure during the process. However, in the present invention, Plasma CVD or atmospheric pressure CVD, which provides the coating property equivalent to that in a common CVD process without the increase in temperature, is preferably employed for forming the inorganic insulating film because the resin substrate is used as the substrate.

The present invention is further a production method of the display device of the present invention, including a step of forming the inorganic base coat film by chemical vapor deposition. That is, the present production method is a method for forming the inorganic base coat film on the resin substrate. The inorganic base coat film also can be formed by CVD similarly to the inorganic insulating film. By CVD, the inorganic base coat film can be formed to cover the organic foreign substances formed on the resin substrate with high coating property, similarly to the above mentioned inorganic insulating film, thereby significantly reducing a probability of pinhole generation due to a coating defect. As a result, permeation of moisture and oxygen into a display element can be effectively prevented, which provides a display device including the display element in which deterioration of characteristics is suppressed. As mentioned above, plasma CVD or atmospheric pressure CVD is preferred as the CVD.

The present invention is further a method for producing the display device of the present invention including a step of forming the organic insulating film in an environment of cleanliness of Class 1. In the present description, cleanliness of Class 1 means cleanliness of an environment in which the number of dusts with a size of not less than 0.5 μm is not more than 1 per cubic foot. The organic insulating film formed in such an environment generates few organic foreign substances thereon. As a result, the inorganic conductive film and the inorganic insulating film cover the surface of the organic insulating film with ease, and therefore permeation of moisture and oxygen into a display element can be effectively prevented, which provides a display device including the display element in which deterioration of characteristics is suppressed.

### EFFECT OF THE INVENTION

According to the display device of the present invention, the inorganic conductive film and the inorganic insulating film covering the entire surface of the organic insulating film effectively prevent permeation of moisture and oxygen, which cannot be prevented only with an electrode used for display, into a display element, and suppress deterioration of characteristics of the display element. Further, even if a portion of the organic insulating film is not covered by the inorganic conductive film and the inorganic insulating film, a longer path of permeation of moisture and oxygen can be secured, and as a result, the effect of preventing the permeation of moisture and oxygen can be obtained.

### BEST MODES FOR CARRYING OUT THE INVENTION

The present invention is mentioned in more detail below with reference to Embodiments using drawings, but not limited thereto.

### Embodiment 1

The display device in accordance with Embodiment 1 of the present invention is a liquid crystal display device. FIG. 1 is a cross-sectional view schematically showing a liquid crystal display device in accordance with Embodiment 1. As shown in FIG. 1, the liquid crystal display device in accordance with Embodiment 1 includes a pair of resin substrates 11 and 21 with a liquid crystal layer 10, which is a display element, therebetween. The resin substrate 11 is included in an array substrate 17 including a pixel electrode 15, and the resin substrate 21 is included in a counter substrate 27 including a color filter 23. For the liquid crystal display device in accordance with Embodiment 1, the array substrate 17 and the counter substrate 27 are separately described in more detail below.

The array substrate 17 included in the liquid crystal display device of Embodiment 1 may be produced as follows. FIG. 2-1 is a cross-sectional view schematically showing the array substrate included in the liquid crystal display device in accordance with Embodiment 1. First, the resin substrate 11 having a thickness of 0.1 mm is prepared, and a transparent inorganic film (an inorganic base coat film) 12 such as a film made of silicon oxide (SiO₂) is then formed to have a thickness of 200 nm on the entire surface of the substrate 11. Other examples of a material for the inorganic base coat film 12 include SiN (silicon nitride), Ta₂O₅ (tantalum pentoxide), and Al₂O₃ (alumina). The inorganic base coat film 12 may be formed, for example, by CVD, sputtering, or vacuum deposition. In order to form a dense film to cover organic foreign substances with high coating property, CVD is preferred. More preferred is plasma CVD or atmospheric pressure CVD. In Embodiment 1, the resin substrate 11 has organic foreign substances 30 on its surface because application of a large amount of a liquid resin and heat curing treatment for the applied resin are performed for making the resin substrate with a thickness of about 100 μm.

Then, a plurality of gate signal lines and a plurality of data signal lines are arranged to cross each other on the inorganic base coat film 12. A region surrounded by the gate signal lines and the data signal lines is defined as one pixel, thus providing the pixels arranged in a matrix pattern. A region where such pixels are arranged is a display region. A TFT 13, which is a switching element, is arranged at an intersection of the gate signal line and the data signal line. The TFT is a three terminal switching element and includes a gate electrode and source/drain electrodes with a semiconductor layer and a gate insulating film therebetween. The gate signal line and the gate electrode are electrically connected each other, and the data signal line is electrically connected to one of the source/drain electrodes. Such a structure allows display control on each pixel basis.

Then, an organic insulating film 14 is applied to cover the inorganic base coat film 12 and the components formed thereon to have a thickness of 2 μm. As a material of the organic insulating film 14, a transparent acrylic resin and the like may be used. The organic insulating film 14 may be formed, for example, by spin coating and photolithography. Thus, the organic insulating film 14 is formed to have a thin thickness, which leads to a reduction in size of the organic foreign substances 30 generated thereon. Therefore coating properties of an inorganic insulating film and an inorganic conductive film mentioned below are improved. The organic insulating film 14 is applied in an environment of extremely high cleanliness of Class 1 (the number of dusts having a size of not less than 0.5 μm per cubic foot is not more than 1), and as a result, the organic foreign substances 30 are less generated. The organic foreign substances generated in the production of the resin substrate 11 typically have a size of several micrometers. So, according to the present Embodiment, the organic insulating film 14 can almost completely cover the organic foreign substances 30.

The organic insulating film 14 in a region just above the TFT 13 is provided with a hole for connecting the TFT 13 with the pixel electrode 15 to be formed thereabove. A conductive film is then formed in the hole and the pixel electrode (an inorganic conductive film) 15 made of ITO (indium tin oxide) and the like is further formed in a position corresponding to the pixel. The pixel electrodes 15 are formed in a matrix pattern with a constant space therebetween, and so such a structure allows display control on each pixel electrode 15 basis.

Then, a silicon nitride (SiN) film (an inorganic insulating film) 16 is formed by CVD in a region other than a region where the pixel electrode 15 is formed, that is, a region where the organic insulating film 14 is exposed. Other examples of a material for the inorganic insulating film 16 include silicon oxide (SiO₂). The inorganic insulating film 16 may be formed by sputtering, vacuum deposition, or the like. In order to form a dense film to cover organic foreign substances with high coating property, CVD used in the present Embodiment is preferred. More preferred is plasma CVD or atmospheric pressure CVD. As a result, the surface of the array substrate 17 facing to the liquid crystal layer 10 can be almost completely covered with the inorganic film.

As shown by the dotted line in FIG. 2-1, moisture and oxygen permeate an organic material such as the resin substrate 11 and the organic insulating film 14. According to the Embodiment 1, even if the organic foreign substances 30 are generated on the resin substrate 11 to form a path of permeation of moisture and oxygen between the resin substrate 11 and the organic insulating film 14, the inorganic conductive film 15 and the inorganic insulating film 16 covering the entire surface of the organic insulating film 14 prevent the permeation of moisture and oxygen into the liquid crystal layer 10.

In Embodiment 1, as described above, the organic insulating film 14 is produced in an environment of very high cleanliness of Class 1 or higher, which leads to a much lower probability of generation of the organic foreign substances. If the production process is not performed in such an environment of high cleanliness and the organic foreign substances 30 are generated on the resin substrate 11 as shown in FIG. 2-2 and organic foreign substances 40 are generated on the organic insulating film 14, a path of permeation of moisture and oxygen leading from outside into the liquid crystal layer 10 would be formed. However, even if the path of permeation of moisture and oxygen is formed, in the present Embodiment, the permeation of moisture and oxygen takes a great deal of time due to the sufficient long path of permeation as shown by the dotted line of FIG. 2-2. Thus, the permeation of moisture and oxygen into the liquid crystal layer (display element) 10 can be substantially prevented. In addition, the organic insulating film 14, which have a thin thickness of 2 μm, contributes to interruption of the permeation of moisture and oxygen.

The counter substrate 27 included in the liquid crystal display device of Embodiment 1 may be produced as follows. FIG. 3-1 is a cross-sectional view schematically showing a counter substrate included in the liquid crystal display device in accordance with Embodiment 1. First, the resin substrate 21 having a thickness of 0.1 mm is prepared similarly to the array substrate, and then a transparent inorganic film (an inorganic base coat film) 22 such as a film made of silicon oxide (SiO₂) is formed to have a thickness of 200 nm on the entire surface of the resin substrate 21. The inorganic base coat film 22 is made of the same material and formed by the same method as those in the production of the array substrate 17.

The color filter 23 is then made of an organic resin (an organic insulating film) in a region facing to the pixel electrode 15 in the array substrate 17. In Embodiment 1, the color filter 23 is composed of a red filter 23R, a green filter 23G, and a blue filter 23B. The black matrix 24 for preventing light leakage is made of an organic resin (an organic insulating film) between the color filters showing respective colors. These organic resins in which a pigment, such as a red pigment, a blue pigment, a green pigment, and a black pigment, is dispersed can represent the respective colors. A thickness of the color filter 23 and the black matrix 24 each may be 2 μm, for example. The color filter 23 and the black matrix 24 may be formed, for example, by printing, inkjet, or the like. Thus, the color filter 23 and the black matrix 24 are each formed to have a thin thickness, which leads to a reduction in size of the organic foreign substances 30 generated thereon. As a result, the coating property of the inorganic insulating film and the inorganic conductive film described below are improved. The color filter 23 and the black matrix 24 are applied in an environment of extremely high cleanliness of Class 1 or higher, so organic foreign substances 30 can be less generated. The organic foreign substances generated in the production of the resin substrate 11 typically have a size of several micrometers. So, according to the present Embodiment, the color filter 23 and the black matrix 24 can almost completely cover the organic foreign substances 30.

Then, a counter electrode (an inorganic conductive film) 25 made of ITO and the like is formed on the color filter 23 and the black matrix 24 in a display region.

Then, a silicon nitride (SiN) film (an inorganic insulating film) 26 is formed by CVD in a region other than the display region where the counter electrode 25 is formed, that is, regions where the color filter 23 or the black matrix 24 is exposed. Other examples of a material for the inorganic insulating film 26 include silicon oxide (SiO₂). The inorganic insulating film 26 is made of the same material and formed by the same method as those used in the production of the array substrate. As a result, the surface of the counter substrate 27 facing to the liquid crystal layer 10 can be almost completely covered with the inorganic films.

As shown by the dotted line in FIG. 3-1, moisture and oxygen permeate an organic material, such as the resin substrate 21, the color filter 23, the black matrix 24, and the like. According to the Embodiment 1, even if the organic foreign substances 30 are generated on the resin substrate 21 to form a path of permeation of moisture and oxygen between the resin substrate 21 and the color filter 23 or between the resin substrate 21 and the black matrix 24, the inorganic conductive film 25 and the inorganic insulating film 26, which are formed to cover the entire surface of the color filter 23 and the black matrix 24, prevent the permeation of moisture and oxygen into the liquid crystal layer 10.

In Embodiment 1, as described above, the color filter 23 and the black matrix 24 are produced in an environment of very high cleanliness of Class 1 or higher, which leads to a much lower probability of generation of the organic foreign substances. If the production process is not performed in such an environment of high cleanliness and the organic foreign substances 30 are generated on the resin substrate 21 as shown in FIG. 3-2 and the organic foreign substances 40 are generated on the color filter 23 or the black matrix 24, a path of permeation of moisture and oxygen leading from outside into the liquid crystal layer 10 would be formed. However, even if the path of permeation of moisture and oxygen is formed, according to the present Embodiment, the permeation of moisture and oxygen takes a great deal of time due to the sufficient long path of permeation as shown by the dotted line of FIG. 3-2. Thus, the permeation of moisture and oxygen into the liquid crystal layer (display element) 10 can be substantially prevented. In addition, the color filter 23 and the black matrix 24, which have a thin thickness of 2 μm, contribute to interruption of the permeation of moisture and oxygen.

The liquid crystal display device of Embodiment 1 (FIG. 1) includes the thus prepared array substrate 17 (FIG. 2-1) and counter substrate 27 (FIG. 3-1). In Embodiment 1, the array substrate 17 and the counter substrate 27 are attached to each other with a sealing member 20 having a thickness of 5 μm made of an epoxy resin with almost no moisture permeability. In this case, if the sealing member 20 has a width of 3 mm, a longer path of permeation of moisture and oxygen can be secured.

As mentioned above, in the present Embodiment, both the array substrate 17 and the counter substrate 27 efficiently block permeation of moisture and oxygen from the outside, which prevents deterioration of the display element of the liquid crystal display device.

As shown in FIG. 4, the inorganic base coat film 12 may be formed on the both surfaces of the resin substrate 11 and the inorganic base coat film 22 may be formed on the both surfaces of the resin substrate 21. So the permeation of moisture and oxygen into such substrates is efficiently prevented. Specifically, permeation of moisture and oxygen from the surfaces of the resin substrates 11 and 21 is prevented and the moisture and oxygen permeate only from end faces of the resin substrates 11 and 21 having a smaller area than that of the substrate surface.

### Embodiment 2

The display device in accordance with Embodiment 2 of the present invention is an organic EL display device. The organic EL display device in accordance with Embodiment 2 includes a resin substrate having an organic EL layer which is a display element.

The organic EL display device of Embodiment 2 may be produced as follows. FIG. 5-1 is a cross-sectional view schematically showing an organic EL display device in accordance with Embodiment 2. First, a resin substrate 51 having a thickness of 0.1 mm is prepared, and on the entire surface of the substrate 51, a transparent inorganic film (an inorganic base coat film) 52 such as a film made of silicon oxide (SiO₂) is formed to have a thickness of 200 nm. Other examples of a material of the inorganic base coat film 52 include SiN (silicon nitride), Ta₂O₅ (tantalum pentoxide), and Al₂O₃ (alumina). The inorganic base coat film 52 may be formed, for example, by CVD, sputtering, or vacuum deposition. In order to form a dense film to cover organic foreign substances with high coating property, CVD is preferred. More preferred is plasma CVD or atmospheric pressure CVD. The inorganic base coat film 52, which is formed on the both surfaces of the resin substrate 51, can further prevent permeation of moisture and oxygen. In Embodiment 2, the resin substrate 51 has organic foreign substances 30 on its surface because application of a large amount of a liquid resin and heat curing treatment for the applied resin are performed for making the resin substrate with a thickness of about 100 μm.

A plurality of gate signal lines and a plurality of data signal lines are then arranged to cross each other on the inorganic base coat film 52. A region surrounded by the gate signal lines and the data signal lines is defined as one pixel, thus providing the pixels arranged in a matrix pattern. A region where such pixels are arranged is a display region. A TFT 53, which is a switching element, is arranged at an intersection of the gate signal line and the data signal line. The TFT is a three terminal switching element and includes a gate electrode and source/drain electrodes with a semiconductor layer and a gate insulating film therebetween. The gate signal line and the gate electrode are electrically connected to each other, and the data signal line is electrically connected to one of the source/drain electrodes. Such a structure allows display control on each pixel basis.

Then, an organic insulating film 54 is applied to cover the inorganic base coat film 52 and the components formed thereon to have a thickness of 2 μm. As a material of the organic insulating film 54, a transparent acrylic resin and the like may be used. The organic insulating film 54 may be formed, for example, by spin coating and photolithography. Thus, the organic insulating film 54 is formed to have a thin thickness, which leads to a reduction in size of the organic foreign substances 60 generated thereon. Therefore coating properties of an inorganic insulating film and an inorganic conductive film mentioned below are improved. The organic insulating film 54 is applied in an environment of extremely high cleanliness of Class 1 or higher, and as a result, the organic foreign substances 60 are less generated. The organic foreign substances 60 generated in the production of the resin substrate 51 typically have a size of several micrometers. So, according to the present Embodiment, the organic insulating film 54 can almost completely cover the organic foreign substances 60.

The organic insulating film 54 in a region just above the TFT 53 is provided with a hole for connecting the TFT 53 with an anode 55 to be formed thereabove. A conductive film is then formed in the hole and the anode (an inorganic conductive film) 55 made of ITO (indium tin oxide) and the like is further formed in a position corresponding to the pixel. The anodes 55 are formed in a matrix pattern with a constant space therebetween, and so such a structure allows display control on each anode 55 basis.

Then, a silicon nitride (SiN) film (an inorganic insulating film) 56 is formed by CVD in a region other than a region where the anode 55 is formed, that is, a region where the organic insulating film 54 is exposed.

Other examples of a material for the inorganic insulating film 56 include silicon oxide (SiO₂). The inorganic insulating film 56 may be formed by sputtering, vacuum deposition, or the like. In order to form a dense film to cover organic foreign substances with high coating property, CVD used in the present Embodiment is preferred. More preferred is plasma CVD or atmospheric pressure CVD. As a result, the inorganic film can almost completely cover the surface of the organic insulating film 54 on the organic EL layer 58.

Then, the organic EL layer 58 is formed on the anode 55. In Embodiment 2, the organic EL layer 58 includes a red light-emitting layer 58R, a green light-emitting layer 58G, and a blue light-emitting layer 58B. As a material for the organic EL layer 58, for example, a polyfluorene compound may be used. The organic EL layer may include, in addition to the light-emitting layers emitting the respective colors, a layer that efficiently transports holes or electrons, the layer being made of a mixture of polyethylenedioxythiophene and polystyrene sulfonate (PEDOT/PSS). One example of the embodiment of such an organic EL layer 58 includes a multilayer where PEDOT/PSS, a polyfluorene compound, and PEDOT/PSS are stacked in this order. They may be formed by ink-jet, mask vacuum deposition, or the like. According to the present Embodiment, a probability of generation of the organic foreign substances is decreased, so the thin organic EL layer 58 can be overall formed to have a thickness of about 100 nm.

A cathode 59 is then formed to entirely cover the inorganic insulating film 56 and the organic EL layer 58. The cathode 59 is not electrically divided for each pixel.

In Embodiment 2, the organic EL display device has a bottom anode structure in which an anode of a pair of electrodes is formed on a resin substrate is shown but may have a bottom cathode structure in which a cathode is formed on a resin substrate.

As shown by the dotted line in FIG. 5-1, moisture and oxygen permeate an organic material such as the resin substrate 51 and the organic insulating film 54. According to the Embodiment 2, even if the organic foreign substances 60 are generated on the resin substrate 51 to form a path of permeation of moisture and oxygen between the resin substrate 51 and the organic insulating film 54, the inorganic conductive film 55 and the inorganic insulating film 56, which cover the entire surface of the organic insulating film 54, prevent the permeation of moisture and oxygen into the organic EL layer 58.

In Embodiment 2, as described above, the organic insulating film 54 is produced in an environment of very high cleanliness of Class 1 or higher, which leads to a much lower probability of generation of the organic foreign substances. If the production process is not performed in such an environment of high cleanliness and the organic foreign substances 60 are generated on the resin substrate 51 as shown in FIG. 5-2 and organic foreign substances 80 are generated on the organic insulating film 54, a path of permeation of moisture and oxygen leading from outside into the organic EL layer 58 would be formed. However, even if the path of permeation of moisture and oxygen is formed, according to the present Embodiment, the permeation of moisture and oxygen takes a great deal of time due to the sufficient long path of permeation as shown by the dotted line of FIG. 5-2. Thus, the permeation of moisture and oxygen into the organic EL layer (display element) 58 can be substantially prevented. In addition, the organic insulating film 54, which have a thin thickness of 2 μm, contributes to interrupt of the permeation of moisture and oxygen.

As a result, according to the present Embodiment, the permeation of moisture and oxygen from outside is effectively prevented, which prevents deterioration of the display element of the organic EL device.

### Embodiment 3

The display device in accordance with Embodiment 3 of the present invention is an inorganic EL display device. The inorganic EL display device of Embodiment 3 has the same configuration as that of Embodiment 2, except that an inorganic EL layer is used as the display element.

As a material for the inorganic EL layer, for example, zinc sulfide (ZnS) may be used. Zinc sulfide (ZnS) containing, for example, copper (Cu) as an emission center emits blue light. Other examples of the emission center include chlorine (Cl), iodine (I), aluminum (Al), and manganese (Mn). The inorganic EL layer may be formed, for example, by spin coating, mask vacuum deposition, or the like.

According to Embodiment 3, the configuration having the similar configuration as Embodiment 2 prevents permeation of moisture and oxygen into the inorganic EL layer, thereby making it harder for the display element to be deteriorated.

The present application claims priority to Patent Application No. 2007-275376 filed in Japan on Oct. 23, 2007 under the Paris Convention and provisions of national law in a designated State, the entire contents of which are hereby incorporated by reference.

### BRIEF DESCRIPTION OF DRAWINGS

FIG. 1 is a cross-sectional view schematically showing a liquid crystal display device in accordance with Embodiment 1.

FIG. 2-1 is a cross-sectional view schematically showing an array substrate included in the liquid crystal display device in accordance with Embodiment 1.

FIG. 2-2 is a cross-sectional view schematically showing another embodiment of the array substrate included in the liquid crystal display device in accordance with Embodiment 1.

FIG. 3-1 is a cross-sectional view schematically showing a counter substrate included in the liquid crystal display device in accordance with Embodiment 1.

FIG. 3-2 is a cross-sectional view schematically showing another embodiment of the counter substrate included in the liquid crystal display device in accordance with Embodiment 1.

FIG. 4 is a cross-sectional view schematically showing another embodiment of the liquid crystal display device in accordance with Embodiment 1.

FIG. 5-1 is a cross-sectional view schematically showing an organic EL display device in accordance with Embodiment 2.

FIG. 5-2 is a cross-sectional view schematically showing another embodiment of the organic EL display device in accordance with Embodiment 2.

FIG. 6 is a cross-sectional view schematically showing a possible configuration of a common liquid crystal display device including a resin substrate

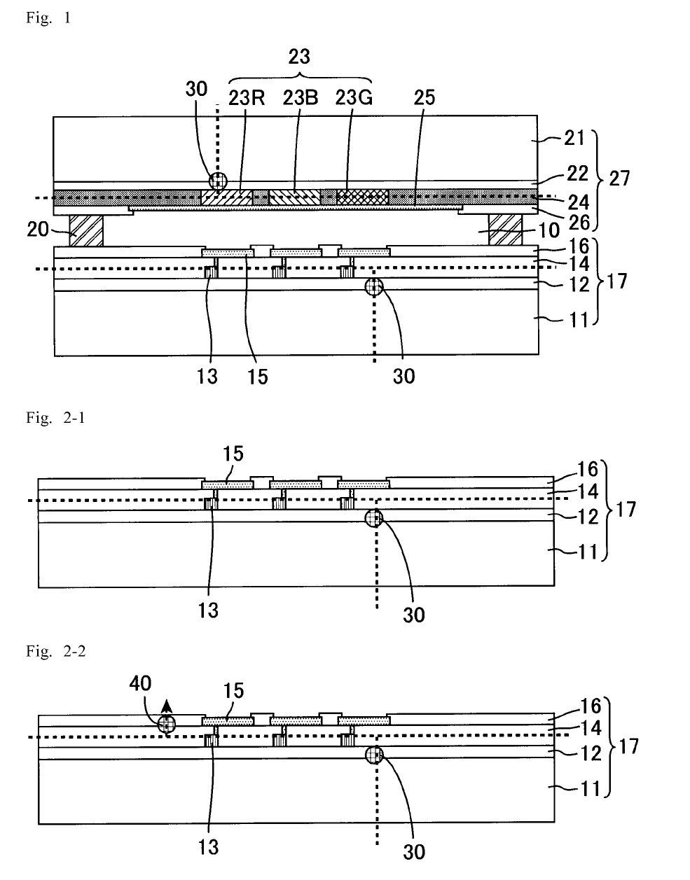

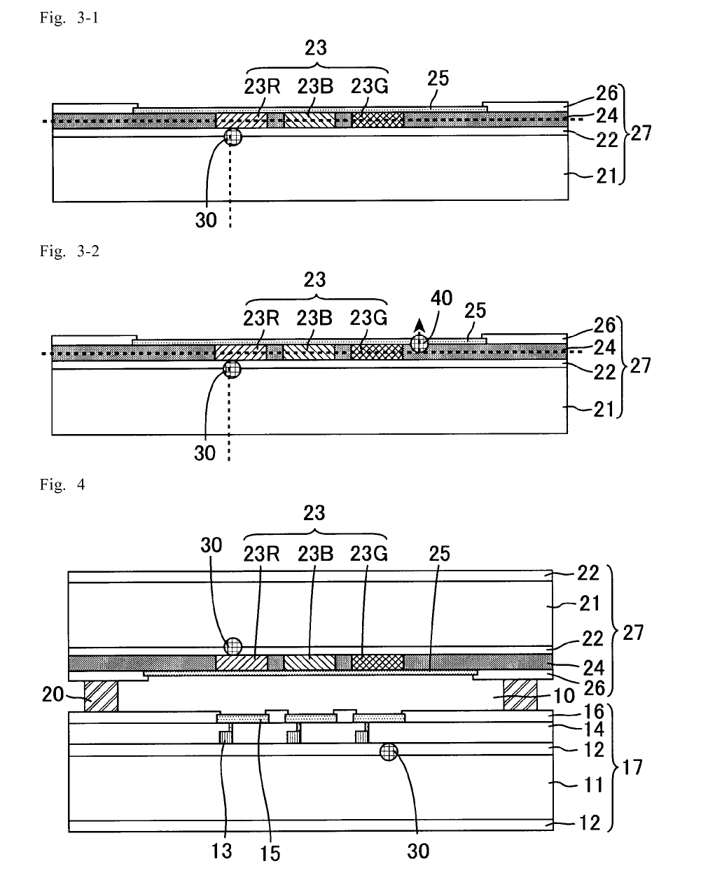

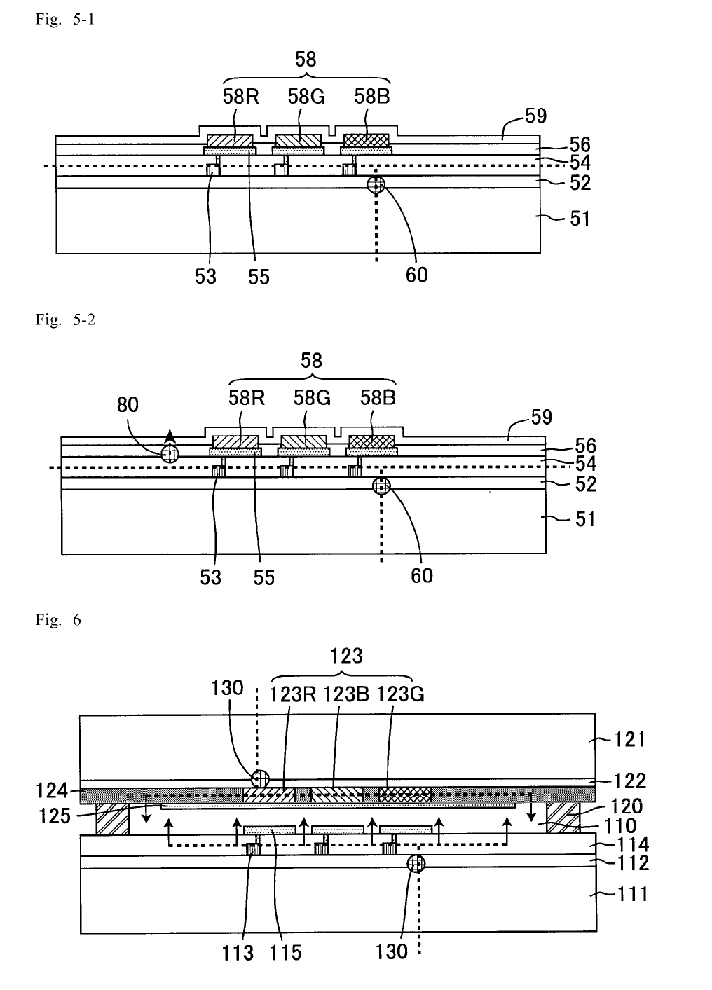

### EXPLANATION OF NUMERALS AND SYMBOLS

10, 110: Liquid crystal layer
11, 21, 51, 111, 121: Resin substrate
12, 22, 52, 112, 122: Inorganic base coat film
13, 53, 113: TFT (thin film transistor)
14, 54, 114: Organic insulating film
15, 55, 115: Pixel electrode (inorganic conductive film)
16, 26, 56: Inorganic insulating film
17: Array Substrate
20, 120: Sealing member
23, 123: Color filter (organic insulating film)
23R, 123R: Color filter (red)
23G, 123G: Color filter (green)
23B, 123B: Color filter (blue)
24, 124: Black matrix (organic insulating film)
25, 125: Counter electrode (inorganic conductive film)
27: Counter substrate
30, 60, 130: Organic foreign substance (on a resin substrate)
40, 80: Organic foreign substance (on an organic insulating film, a color filter, or a black matrix)
55: Anode
58: Organic EL layer
58R: Organic EL layer (Red)
58G: Organic EL layer (green)
58B: Organic EL layer (Blue)
59: Cathode

1. A display device comprising:
a resin substrate; and
an organic insulating film, an inorganic conductive film, and a display element, formed on the resin substrate in this order,
wherein the display device comprises an inorganic insulating film arranged adjacent to the inorganic conductive film, the inorganic insulating film and the inorganic conductive film covering the entire surface of the organic insulating film.

2. The display device according to claim 1,
comprising an inorganic base coat film disposed between the resin substrate and the organic insulating film,
the inorganic base coat film covering the entire surface of the resin substrate.

3. The display device according to claim 2,
wherein the inorganic base coat film is arranged on both surfaces of the resin substrate.

4. The display device according to claim 1
comprising gate signal lines, data signal lines, and thin film transistors on the resin substrate,
wherein the inorganic conductive film constitutes a pixel electrode arranged in a region surrounded by the gate signal lines and the data signal lines.

5. The display device according to claim 1,
wherein the organic insulating film constitutes a color filter.

6. The display device according to claim 1,
wherein the organic insulating film constitutes a black matrix.

7. The display device according to claim 1,
wherein the organic insulating film has a thickness of not more than 10 μm.

8. The display device according to claim 1,
wherein the display element is a liquid crystal layer.

9. The display device according to claim 1,
wherein the display element is an electroluminescent layer.

10. A production method of the display device according to claim 1,
comprising a step of forming the inorganic insulating film by chemical vapor deposition.

11. A production method of the display device according to claim 2,
comprising a step of forming the inorganic base coat film by chemical vapor deposition.

12. A method for producing the display device according to claim 1,
comprising a step of forming the organic insulating film in an environment of cleanliness of Class 1.
